(19) United States
(12) Patent Application Publication
(10) Pub. No.: US 2015/0371573 A1
(43) Pub. Date: Dec. 24, 2015

(54) DISPLAY DEVICE

(71) Applicant: Samsung Display Co., Ltd., Yongin-City (KR)

(72) Inventors: Jinwoo Choi, Yongin-City (KR); Hongshik Shim, Yongin-City (KR); Haeyun Choi, Yongin-City (KR)

(21) Appl. No.: 14/644,024

(22) Filed: Mar. 10, 2015

(30) Foreign Application Priority Data
Jun. 23, 2014 (KR) 10-2014-0076776

(51) Int. Cl. G09G 3/00; H01L 27/32; G09G 3/32; H01L 51/52

(52) U.S. Cl. CPC G09G 3/003; H01L 51/5284; H01L 27/322; H01L 27/3225; H01L 51/5271; H01L 27/3246; H01L 51/5237; G09G 3/3225; H01L 2251/5338; H01L 2251/5315; H01L 2251/5323; G09G 2300/0408; G09G 2300/08; G09G 2320/068

(57) ABSTRACT

A display device is disclosed. In one aspect, the display device includes a first substrate, a second substrate facing the first substrate, and a display unit comprising a plurality of emission areas formed over a surface of the first substrate facing the second substrate. The display device also includes a plurality of black matrices formed over a surface of the second substrate facing the first substrate, the black matrices at least partially overlapping side portions of the pixels, and a gap controller formed between the first and second substrates and configured to adjust a gap therebetween.

### CROSS-REFERENCE TO RELATED APPLICATIONS

This application claims the benefit of Korean Patent Application No. 10-2014-0076776, filed on Jun. 23, 2014, in the Korean Intellectual Property Office, the disclosure of which is incorporated herein in its entirety by reference.

### BACKGROUND

1. Field

The described technology generally relates to a display device.

2. Description of the Related Technology

Due to developments in information technology, the market for display devices as interface media between users and information has increased. Many types of display devices have been developed such as organic light-emitting diode (OLED) displays, liquid crystal displays (LCDs), electro wetting display devices (EWDs), plasma display panels (PDPs), and electrophoretic displays (EPDs). Among these types, OLED displays have excellent characteristics such as a thin profile, light-weight, and low power consumption.

Currently, display devices are widely used in electronic devices such as mobile communication terminals, digital cameras, notebooks, monitors, TVs, or the like that are commonly used. Demand for flexible displays has also increased.

### SUMMARY OF CERTAIN INVENTIVE ASPECTS

One inventive aspect is a display device of which a viewing angle mode can be selected by a user according to circumstances.

Another aspect is a display device that includes a first substrate; a second substrate formed to face the first substrate; a display unit including a plurality of emission areas formed on a surface of the first substrate that faces the second substrate, wherein the surface is one of surfaces of the first substrate, and wherein a plurality of organic light-emitting devices are formed in the plurality of emission areas, respectively; a plurality of black matrixes formed on a surface of the second substrate that faces the first substrate, and overlapping side portions of the plurality of emission areas, wherein the surface is one of surfaces of the second substrate; and a gap controller formed between the first substrate and the second substrate and configured to adjust a gap between the first substrate and the second substrate.

The display device can further include a plurality of color filters that are formed adjacent to the plurality of black matrixes so as to correspond to the plurality of emission areas, respectively.

The gap controller can adjust the gap by contracting or expanding according to an electrical signal.

The gap controller can adjust the gap by using a piezoelectric actuator that contracts or expands according to the electrical signal.

The piezoelectric actuator of the gap controller can be formed around the display unit between the first substrate and the second substrate.

The piezoelectric actuator of the gap controller can be formed in a region overlapping the display unit between the first substrate and the second substrate.

The gap controller can include a controller for receiving viewing angle mode information and generating a control signal according to the viewing angle mode information; and a driver for receiving the control signal, generating the electrical signal according to the control signal, and providing the electrical signal to the piezoelectric actuator.

The gap controller can further include a sensor unit for detecting the gap between the first substrate and the second substrate.

The controller can generate the control signal based on a difference between a target gap according to the viewing angle mode information and a current gap that is detected by the sensor unit.

In a wide viewing angle mode, the piezoelectric actuator can contract so that the gap is decreased.

In a narrow viewing angle mode, the piezoelectric actuator can expand so that the gap is increased.

The display device can further include a plurality of reflective members that are formed outside the plurality of emission areas, respectively, and that reflect light emitted from the plurality of organic light-emitting devices.

The display unit can further include pixel-defining layers for defining the plurality of emission areas, and the plurality of reflective members can be formed in the pixel-defining layers, respectively.

The reflective member can be formed on a path where light that is horizontally emitted from the organic light-emitting device is emitted toward another adjacent emission area among the plurality of emission areas.

A surface among surfaces of the reflective member which faces the organic light-emitting device can have an inclined surface.

The display device can further include an encapsulation member that is formed on the first substrate so as to cover the display unit and includes one or more stacked insulating layers.

Light can be emitted from the plurality of organic light-emitting devices toward the second substrate or toward the second substrate and the first substrate.

Another aspect is a display device comprising a first substrate, a second substrate facing the first substrate, a display unit comprising a plurality of emission areas formed over a surface of the first substrate facing the second substrate, and a plurality of black matrices formed over a surface of the second substrate facing the first substrate, wherein the black matrices at least partially overlap side portions of the emission areas. The display device also comprises a gap controller formed between the first and second substrates and configured to adjust a gap therebetween.

The above display device further comprises a plurality of color filters formed adjacent to the black matrices and respectively corresponding to the emission areas. In the above display device, the gap controller is further configured to increase or decrease the gap based at least in part on an electrical signal.

In the above display device, the gap controller comprises a piezoelectric actuator configured to contract or expand based at least in part on the electrical signal. In the above display device, the piezoelectric actuator is formed in the sides of the display unit between the first and second substrates. In the above display device, the piezoelectric actuator is formed in a region at least partially overlapping the display unit between the first and second substrates.

In the above display device, the gap controller further comprises a controller configured to i) receive viewing angle mode information and ii) generate a control signal based at least in part on the viewing angle mode information. In the above display device, the gap controller further comprises a driver configured to i) receive the control signal from the controller, ii) generate the electrical signal based at least in part on the control signal, and iii) provide the electrical signal to the piezoelectric actuator.

In the above display device, the gap controller further comprises a sensor configured to detect a size of the gap between the first and second substrates. In the above display device, the controller is further configured to generate the control signal based at least in part on a difference between a target gap corresponding to the viewing angle mode information and a current gap detected by the sensor.

In the above display device, in a wide viewing angle mode, the piezoelectric actuator is further configured to contract so as to decrease the gap. In the above display device, in a narrow viewing angle mode, the piezoelectric actuator is further configured to expand so as to increase the gap.

The above display device further comprises a plurality of reflective members respectively formed outside the pixels and configured to reflect light output from a plurality of organic light-emitting diodes (OLEDs).

In the above display device, the display unit further comprises pixel-defining layers that define the emission areas, wherein the reflective members are respectively formed in the pixel-defining layers.

In the above display device, the reflective member is formed on a path where light, substantially horizontally output from a selected one of the OLEDs toward an adjacent OLED.

In the above display device, a selected on of the reflective members has an inclined surface facing the one of the OLEDs.

The above display device further comprises an encapsulation member formed over the first substrate so as to at least partially cover the display unit and comprising at least one insulating layer.

In the above display device, a plurality of OLEDs are configured to output light toward the second substrate or toward the first and second substrate.

Another aspect is a flexible display comprising first and second flexible substrates facing each other, a display unit comprising a plurality of pixels formed over a surface of the first flexible substrate facing the second flexible substrate, and a gap controller formed between the first and second flexible substrates and configured to adjust a gap therebetween.

In the above display device, the gap controller is further configured to increase or decrease the gap based at least in part on an electrical signal.

In the above display device, the gap controller comprises a piezoelectric actuator configured to contract or expand based at least in part on the electrical signal.

### BRIEF DESCRIPTION OF THE DRAWINGS

FIG. 1 is a cross-sectional view of a display device according to an embodiment.

FIG. 2 is a cross-sectional view illustrating a portion of the display device of FIG. 1.

FIG. 3 is a cross-sectional view illustrating a portion of the display device of FIG. 1 when the display device is in a wide viewing angle mode.

FIG. 4 is a cross-sectional view illustrating a portion of the display device of FIG. 1 when the display device is in a narrow viewing angle mode.

FIG. 5 is a block diagram illustrating a configuration of a gap controller in the display device of FIG. 1.

FIG. 6 is a cross-sectional view that illustrates a portion of the display device of FIG. 1 when color mixing occurs.

FIG. 7 is a cross-sectional view illustrating a portion of a display device, according to another embodiment.

### DETAILED DESCRIPTION OF CERTAIN INVENTIVE EMBODIMENTS

As the described technology allows for various changes and numerous embodiments, particular embodiments will be illustrated in the drawings and described in detail in the written description. However, this is not intended to limit the described technology to particular modes of practice, and it is to be appreciated that all changes, equivalents, and substitutes that do not depart from the spirit and technical scope are encompassed in the described technology. In the description, certain detailed explanations of related art are omitted when it is deemed that they can unnecessarily obscure the essence of the described technology.

While such terms as “first,” “second,” etc., can be used to describe various components, such components must not be limited to the above terms. The above terms are used only to distinguish one component from another.

Throughout the specification, it will also be understood that when an element such as layer, film, region, substrate, etc. is referred to as being “on” another element, it can be directly on the other element, or intervening elements can also be present

Reference will now be made in detail to embodiments, examples of which are illustrated in the accompanying drawings, wherein like reference numerals refer to like elements throughout, and redundant descriptions thereof are omitted. In the drawings, the thicknesses of layers and regions are exaggerated for clarity and for convenience of description.

As used herein, the term “and/or” includes any and all combinations of one or more of the associated listed items. Expressions such as “at least one of,” when preceding a list of elements, modify the entire list of elements and do not modify the individual elements of the list. In this disclosure, the term “substantially” includes the meanings of completely, almost completely or to any significant degree under some applications and in accordance with those skilled in the art. Moreover, “formed on” can also mean “formed over.” The term “connected” can include an electrical connection.

One or more embodiments can be provided in various display devices such as organic light-emitting diode (OLED) displays, liquid crystal displays (LCDs), or the like. However, the characteristics of one or more embodiments will now be described in detail with reference to an OLED display.

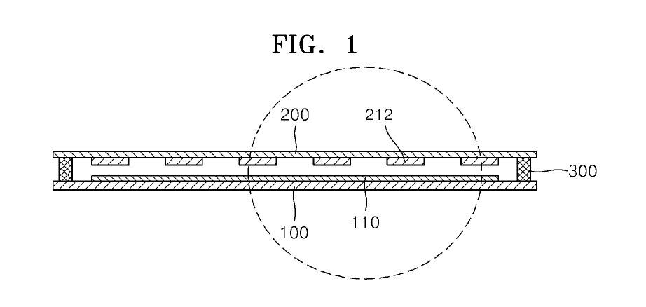

FIG. 1 is a cross-sectional view of a display device according to an embodiment.

Referring to FIG. 1, the display device includes a first substrate 100, a display unit 110 formed over the first substrate 100, a second substrate 200, a black matrix 212 formed over the second substrate 200, and a gap controller 300 that adjusts a gap between the first substrate 100 and the second substrate 200.

The first substrate 100 can be formed of various materials.

The first substrate 100 can be formed of a flexible material. For example, the first substrate 100 includes a plastic material such as polyethyeleneterepthalate (PET), polyethyelenennapthalate (PEN), polycarbonate (PC), polyallylate, polyetherimide (PEI), polyethersulphone (PES), or polyimide (PI) that has excellent heat-resistance and durability. When the first substrate 100 is formed of the flexible material, it is possible to prevent the first substrate 100 and the second substrate 200 from being damaged when the gap between the first and second substrates 100 and 200 is mechanically adjusted.

However, one or more embodiments are not limited thereto, and the first substrate 100 can be formed of other various flexible materials.

In some embodiments, the first substrate 100 is formed of various materials including a glass material, a metal material, or the like.

Similar to the first substrate 100, the second substrate 200 can be formed of various materials. The second substrate 200 can be formed of one of the aforementioned various materials for forming the first substrate 100.

In the present embodiment, if the display device is a top emission type display device in which an image is realized toward the second substrate 200, the second substrate 200 is formed of a transparent material. However, the first substrate 100 is not necessarily formed of a transparent material. Conversely, in the present embodiment, if the display device is a bottom emission type display device in which an image is realized toward the first substrate 100, the first substrate 100 is formed of a transparent material while the second substrate 200 is not necessarily formed of a transparent material.

If one of the first and second substrates 100 and 200 is not formed of a transparent material, the other one can be formed of an opaque material, e.g., an opaque metal. When one of the first and second substrates 100 and 200 is formed of a metal material, the other one can be formed of at least one material selected from the group including carbon, iron, chromium, manganese, nickel, titanium, molybdenum, and stainless steel (SUS), but is not limited thereto. The display unit 110 is formed on a top surface of the first substrate 100. Throughout the specification, the display unit 110 collectively refers to OLED and a thin-film transistor (TFT) array for driving the OLED and indicates both an area for displaying an image and another area for driving the area.

However, the embodiments are not limited thereto. That is, the display unit 110 can include an LCD. For convenience of description, the OLED formed is described as an example in the present embodiment.

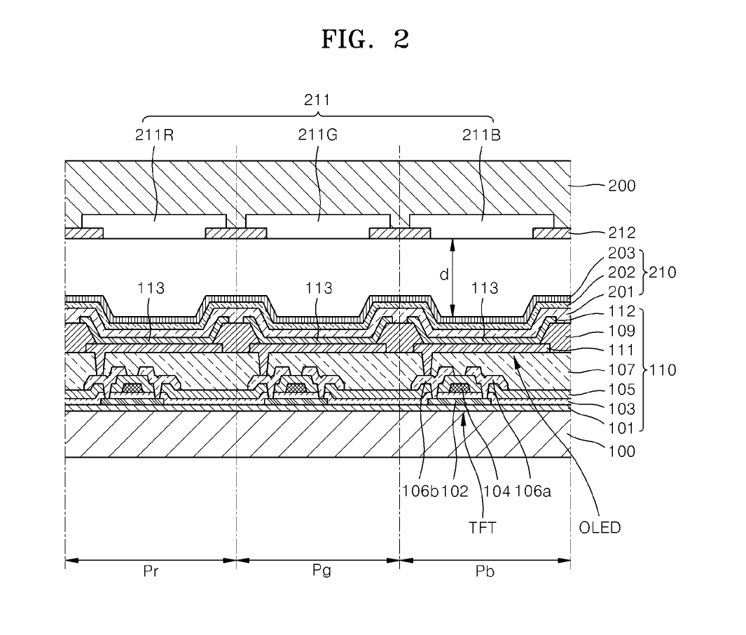

An encapsulation member 210 (see FIG. 2) is formed over the first substrate 100 so as to at least partially cover the display unit 110. An OLED included in the display unit 110 is formed of an organic material and thus can easily deteriorate due to external moisture or oxygen. Thus, the encapsulation member 210 is arranged so as to protect the display unit 110. The encapsulation member 210 can be formed of an organic material or an inorganic material.

In some embodiments, the encapsulation member 210 is formed of one or more organic layers or one or more inorganic layers. For example, the encapsulation member 210 has a structure in which at least one organic layer and at least one inorganic layer are alternately stacked at least once.

By arranging the encapsulation member 210 so as to protect the display unit 110, a slim and flexible display device can be easily manufactured.

FIG. 2 is a cross-sectional view illustrating a portion of the display device of FIG. 1. FIG. 2 illustrates a cross-section of the display unit 110 and a cross-section of the encapsulation member 210. When the display unit 110 is a planar structure, a plurality of pixels are formed in a matrix shape.

The pixels can emit visible light of various colors.

In some embodiments, the pixels can include at least a red pixel Pr that generates a red visible ray, a green pixel Pg that generates a green visible ray, and a blue pixel Pb that generates a blue visible ray.

Each of the pixels includes an OLED.

In some embodiments, each pixel includes an electronic device that is electrically connected to the OLED. The electronic device can include at least one TFT, a storage capacitor, or the like. The electronic device can transmit various types of electrical signals for driving the OLED to emit light.

Although FIG. 2 illustrates only the OLED and the TFT, this is for convenience of description only. However, embodiments are not limited thereto. Each pixel can further include a plurality of the TFTs, a storage capacitor, and various wirings.

The TFT shown in FIG. 2 is a top gate type TFT, and sequentially includes an active layer 102, a gate electrode 104, and a source electrode 106a and a drain electrode 106b. Although the present embodiment discloses the top gate type TFT, embodiments are not limited to the top gate type shown in FIG. 2. For example, a bottom gate type TFT is used in the display device.

In order to make the top surface of the first substrate 100 substantially flat and to prevent penetration of foreign substances into the top surface, a buffer layer 101 can be formed on the top surface of the first substrate 100. The buffer layer 101 can be deposited by using SiO₂ and/or SiNx by using various deposition methods including a plasma enhanced chemical vapor deposition (PECVD) method, an atmospheric pressure CVD (APCVD) method, a low pressure CVD (LPCVD) method, or the like. In some embodiments, the buffer layer 101 is not formed.

The active layer 102 is formed in a region on the buffer layer 101 which corresponds to each pixel. The active layer 102 can be formed by forming an inorganic semiconductor such as silicon or an oxide semiconductor or an organic semiconductor on substantially the entire surface of the buffer layer 101 and then patterning the inorganic or organic semiconductor.

In some embodiments, if the active layer 102 is formed of silicon, an amorphous silicon layer is used.

In some embodiments, the active layer 102 is formed of a polysilicon layer formed by crystallizing amorphous silicon.

In some embodiments, the active layer 102 includes a source region into which impurities are injected, a drain region, and a channel region between the source region and the drain region.

A gate insulating layer 103 is formed on the active layer 102 so as to insulate the active layer 102 and the gate electrode 104. The gate insulating layer 103 can be formed of various insulating materials. For example, the gate insulating layer 103 is formed of an oxide or nitride.

The gate electrode 104 is formed in a predetermined region on the gate insulating layer 103. In some embodiments, the gate electrode 104 is electrically connected to a gate line (not shown) that transmits an ON or OFF signal of the TFT.

An interlayer insulating layer 105 is formed over the gate electrode 104. The source electrode 106a and the drain electrode 106b contact different regions of the active layer 102 via contact holes. For example, the source electrode 106a and the drain electrode 106b respectively contact a source region and a drain region of the active layer 102. In some embodiments, the TFT is substantially covered and thus protected by a passivation layer 107.

Regarding the passivation layer 107, an inorganic insulating layer and/or an organic insulating layer can be used. The inorganic insulating layer can be formed of SiO₂, SiNx, SiON, Al₂O₃, TiO₂, Ta₂O₅, HfO₂, ZrO₂, BST, or PZT, and the organic insulating layer can be formed of polymer derivatives having commercial polymers (PMMA and PS) and a phenol group, an acryl-based polymer, an imide-based polymer, an allyl ether-based polymer, an amide-based polymer, a fluorine-based polymer, a p-xylene-based polymer, a vinylalcohol-based polymer, or a combination thereof. The passivation layer 107 can be formed as a multi-stack including the inorganic insulating layer and the organic insulating layer.

The OLED is formed in an emission area above the passivation layer 107.

The OLED can include a pixel electrode 111 that is formed on the passivation layer 107, an opposite electrode 112 that faces the pixel electrode 111, and an intermediate layer that is interposed between the pixel electrode 111 and the opposite electrode 112 and includes an organic emission layer.

The display device can be classified as a bottom emission type display device, a top emission type display device, and a dual emission type display device. If the display device is a bottom emission type display device, the pixel electrode 111 is formed as a transflective electrode, and the opposite electrode 112 is formed as a reflective electrode. If the display device is a top emission type display device, the pixel electrode 111 is formed as a reflective electrode, and the opposite electrode 112 is formed as a transflective electrode. In the present embodiment, it is considered that the top emission type display device includes the OLED that emits light toward the encapsulation member 210.

The pixel electrode 111 can include a reflective layer formed of Ag, Mg, Al, Pt, Pd, Au, Ni, Nd, Ir, Cr, or compound of any of these, and a light-transmitting layer formed of ITO, IZO, ZnO, or In₂O₃ having a high work function. The pixel electrode 111 can be patterned to form an island that corresponds to each pixel. Also, the pixel electrode 111 can be connected to an external terminal (not shown) and can function as an anode electrode.

A pixel-defining layer (PDL) 109 having an opening that covers side portions of the pixel electrode 111 and exposes a center portion of the pixel electrode 111 is formed on the pixel electrode 111. Afterward, an organic emission layer 113 that emits light is formed in a region over the opening to define an emission area. When the emission area is formed in the pixel-defining layer 109, a portion that protrudes more than the emission area is naturally formed between emission areas, and since the organic emission layer 113 is not formed in the portion, the portion corresponds to a non-emission area.

The opposite electrode 112 can be formed as a transmissive electrode having a transflective layer formed of a thin metal such as Li, Ca, LiF/Ca, LiF/Al, Al, Mg, or Ag that has a small work function. By forming a light-transmitting conductive layer such as ITO, IZO, ZnO, or In₂O₃ on the metal transflective layer, a high resistance problem occurring due to a small thickness of the metal transflective layer can be resolved. The opposite electrode 112, as a common electrode, can be formed on substantially the entire surface of the first substrate 100. Also, the opposite electrode 112 can be connected to an external terminal (not shown) and can function as a cathode electrode.

Polarities of the electrode 111 and the opposite electrode 112 can be reversed.

The intermediate layer can include the organic emission layer 113 that emits light. The organic emission layer 113 can be formed of a polymer organic material or a small molecule organic material.

In some embodiments, the intermediate layer include the organic emission layer 113 and further includes at least one selected from a hole transport layer (HTL), a hole injection layer (HIL), an electron transport layer (ETL), and an electron injection layer (EIL). In some embodiments, when the organic emission layer 113 is formed of the polymer organic material, only the HTL is formed between the organic emission layer 113 and the pixel electrode 111. The polymer HTL is formed of poly(3,4-ethylenedioxythiophene) (PEDOT) or polyaniline (PANI) and is formed on the pixel electrode 111 by using an inkjet printing method or a spin coating method.

In the present embodiment of FIG. 2, when the pixel electrode 111 and the opposite electrode 112 are electrically driven, the OLED emits white light. The white light that is emitted from the organic emission layer 113 can have an excellent color rendering index (CRI) (>75) and can be close to (0.33, 0.33) coordinates on the CIE diagram, but embodiments are not limited thereto.

In order to make the organic emission layer 113 emit white light, a down conversion-type wave conversion method whereby a phosphor is excited to emit a blue color or a purple color and other various colors emitted therefrom are mixed to create a wavelength spectrum having a wide and rich domain can be used. Also, a color mixing method whereby two basic colors (blue and orange colors) or three basic colors (red, green, and blue colors) are mixed to create white light can be used. However, embodiments are not limited thereto, and various materials and methods for obtaining white light can be used.

Also, in some embodiments, the organic emission layer 113 does not always emit white light, and instead emits a red color, a green color, or a blue color for each pixel.

Referring to FIG. 2, the encapsulation member 210 is formed over the first substrate 100 so as to at least partially cover the display unit 110. The encapsulation member 210 is formed of a plurality of stacked insulating layers. For example, the insulating layers have a structure where an organic layer 202 and inorganic layers 201 and 203 are stacked in an alternating manner.

The inorganic layers 201 and 203 can be formed of metal oxide, metal nitride, metal carbide, or compound of any of these, e.g., aluminum oxide, silicon oxide, or silicon nitride. The inorganic layers 201 and 203 can prevent penetration of external moisture and oxygen into the OLED. The organic layer 202 can be formed of a polymer organic compound including at least one of acrylate and urethane acrylate. The organic layer 202 can decrease an inner stress of the inorganic layers 201 and 203, resolve a defect of the inorganic layers 201 and 203, and planarize the inorganic layers 201 and 203.

However, a structure of the encapsulation member 210 is not limited to that shown in FIG. 2, and can include at least one sandwich structure in which at least one organic layer is inserted between at least two inorganic layers. In some embodiments, the encapsulation member 210 includes at least one sandwich structure in which at least one inorganic layer is inserted between at least two organic layers. In some embodiments, the encapsulation member 210 can include at least one sandwich structure in which at least one organic layer is inserted between at least two inorganic layers and at least one sandwich structure where at least one inorganic layer is inserted between at least two organic layers. An uppermost layer that is externally exposed in the encapsulation member 210 can be formed of an inorganic layer in order to prevent water vapor transmission.

Here, an area of the at least one organic layer can be smaller than an area of the inorganic layer formed on the at least one organic layer. In some embodiments, the at least one organic layer can be completely covered by the inorganic layer formed on the at least one organic layer.

As described above, a plurality of the black matrixes 212 are formed on the second substrate 200. The black matrix 212 corresponds to the non-emission area.

In some embodiments, the black matrix 212 can have an opening that corresponds to the emission area. Here, a shape of the black matrix 212 is not limited to a rectangular cross-section shown in FIG. 2 and can have a trapezoid shape, a reversedly-trapezoid shape, or the like. The black matrix 212 can prevent visible lights of different colors emitted by the pixels from being abnormally mixed or affecting each other. Also, the black matrix 212 can prevent elements of the TFT from being damaged by external light.

The black matrix 212 can be formed of various materials. In some embodiments, the black matrix 212 can be easily formed by using a black organic material that is a mixture of black pigments, or chrome oxide. Also, as described below, in order to achieve an effect where a viewing angle varies based at least in part on an increase or decrease in a gap between the OLED and the second substrate 200, the black matrix 212 substantially blocks at least a portion of light that is emitted from the emission area.

A method of manufacturing the black matrix 212 can vary depending on a material for forming the black matrix 212. When the black matrix 212 is formed of chrome or chrome oxide that is generally used, a single layer including chrome or chrome oxide is formed by using a sputtering method or an E-beam deposition method. Alternatively, double layers or triple layers can be formed by using chrome or chrome oxide.

In some embodiments, the display device of FIG. 2 includes color filters 211 that respectively correspond to the emission areas.

For example, the color filters 211 are formed in openings of the black matrixes 212. The color filter 211 can be formed to at least partially fill an opening that corresponds to an emission area between the black matrixes 212, and in this case, a portion of the color filter 211 can overlap with portions of the black matrices 212. However, embodiments are not limited thereto, and the color filter 211 can be formed so that a thickness of the color filter 211 can be substantially equal to a thickness of the black matrix 212.

The color filter 211 can be formed of a coloring material and an organic material in which the coloring material is dispersed. The coloring material can be a general pigment or a dye, and the organic material can be a general dispersant. The color filter 211 can selectively transmit specific wavelength light such as green light, red light, or blue light among white light that is emitted from the OLED, and absorb light of no specific wavelength, so that each pixel can emit one of red light, green light, and blue light. As described, color filters 211R, 211G, and 211B having red, green, and blue colors, respectively, are formed while corresponding to the emission areas. Each of the emission areas can emit green light, red light, or blue light.

However, the embodiments are not limited thereto, and when a visible light having a predetermined color, e.g., a visible red light, a visible green light, or a visible blue light is emitted from the OLED, the color filters 211R, 211G, and 211B (also referred as the red, green, and blue color filters 211R, 211G, and 211B, respectively) can enhance a luminescent quality of the visible lights.

The color filter 211 can be manufactured by using a pigment dispersing method, a printing method, an electrodeposition method, a film transfer method, or a heat transfer method.

Although not illustrated, in order to increase an adherence between the color filter 211 and the second substrate 200, a buffer layer (not shown) formed of silicon dioxide (SiO₂) or silicon nitride (SiNx). Alternatively, the color filter 211 can be planarized by forming a protective layer (not shown) on the color filter 211, and then the buffer layer can be formed.

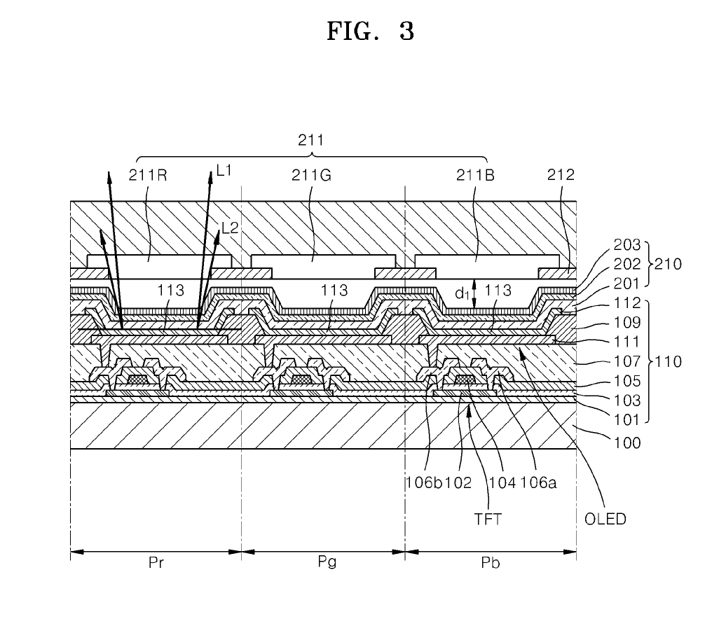

FIG. 3 is a cross-sectional view illustrating a portion of the display device of FIG. 1 when the display device is in a wide viewing angle mode.

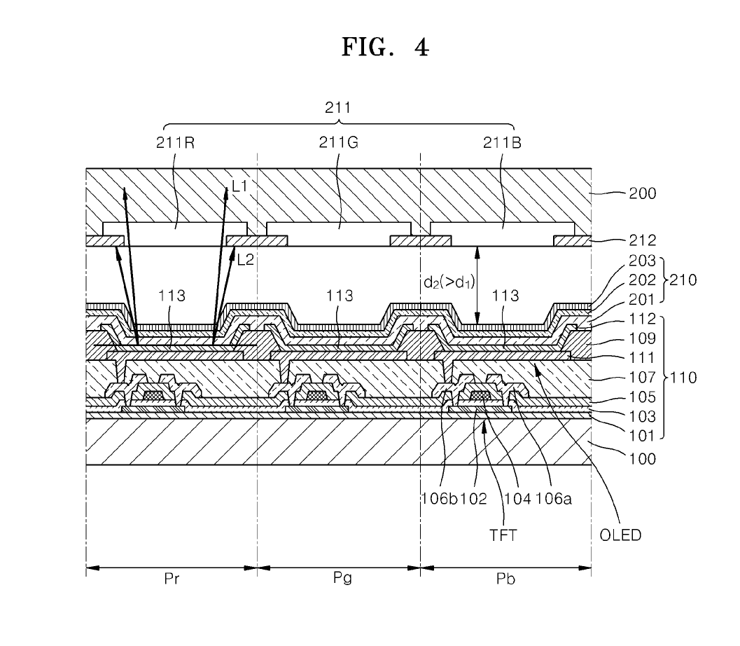

FIG. 4 is a cross-sectional view illustrating a portion of the display device of FIG. 1 when the display device is in a narrow viewing angle mode.

Like reference numerals in FIGS. 2, 3, and 4 denote like components. Since the same components operate or function in an identical or similar manner, repeated descriptions thereof are omitted below.

In general, the display device is designed to be appropriate for a wide viewing angle mode. However, in places such as public areas where many people circulate, content displayed on the display device has to be protected from other people's eyes. That is, it can be necessary that only a narrow region is displayed on the display device in a narrow viewing angle mode.

To do so, the present embodiment provides a display device capable of operating in both a wide viewing angle mode and a narrow viewing angle mode by adjusting a gap (hereinafter, referred to as ‘cell gap’) between the OLED at least partially covered by the encapsulation member 210 and an extended line of a bottom surface of the black matrix 212. Hereinafter, a viewing angle variation due to the cell gap will be described in detail. As illustrated in FIG. 3, when a cell gap d1 is small, light L1 emitted at a first angle from a virtual vertical line and light L2 emitted at a second angle greater than the first angle both pass through an opening. However, as illustrated in FIG. 4, when a cell gap d2 is greater than a cell gap d1, the light L1 passes through an opening, but the light L2 does not pass through the opening and is blocked by the black matrix 212. Here, each of the light L1 and the light L2 of FIG. 3 is respectively emitted at substantially the same angle as that of L1 and L2 of FIG. 4.

In other words, when the cell gap d1 is small as shown in FIG. 3, the quantity of emitted light that passes through the opening is large, and thus, a range of an image to be displayed on the display device becomes large so that the wide viewing angle mode is realized. Conversely, as illustrated in FIG. 4, when the cell gap d2 is greater than the cell gap d1, the quantity of emitted light that passes through the opening is small, and thus, a range of an image to be displayed on the display device becomes small so that the narrow viewing angle mode is realized.

However, the embodiments are not limited to the aforementioned example where the light emitted from the OLED is emitted toward the second substrate 200. The light can be emitted toward both the second substrate 200 and the first substrate 100.

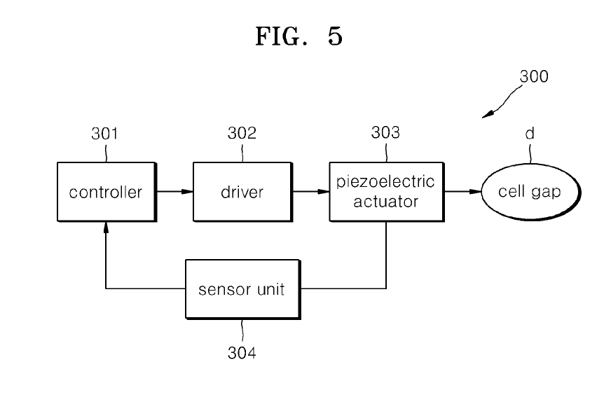

FIG. 5 is a block diagram illustrating a configuration of the gap controller 300 in the display device of FIG. 1.

The gap controller 300 can control a gap between the first substrate 100 and the second substrate 200 based at least in part on a user's intention. For example, the gap controller 300 can control the gap between the first and second substrates 100 and 200 by using an electrical signal input by the user.

In some embodiments, the gap controller 300 includes a piezoelectric actuator 303 that contracts or expands based at least in part on an electrical signal applied thereto and thus adjusts the gap between the first substrate 100 and the second substrate 200.

The piezoelectric actuator 303 of the gap controller 300 can be formed between the first and second substrates 100 and 200. In embodiments, the gap controller 300 is formed in side regions of the first and second substrates 200, e.g., in an outside region of the display unit 110.

In some embodiments, the gap controller 300 is formed so as to at least partially overlap the display unit 110. For example, the gap controller 300 functions as a spacer.

The gap controller 300 includes a controller 301 that receives viewing angle mode information and generates a control signal based at least in part on the viewing angle mode information. The gap controller 300 also includes a driver 302 that receives the control signal, generates an electrical signal based at least in part on the control signal, and provides the electrical signal to the piezoelectric actuator 303.

Also, in some embodiments, the gap controller 300 further includes a sensor unit 304 that detects a gap between the first and second substrate 100 and 200.

Hereinafter, a method of controlling a cell gap dl based at least in part on a viewing angle mode, the method performed by using the gap controller 300, will be described in detail.

Referring to FIG. 5, first, the sensor unit 304 detects a gap between the first and second substrates 100 and 200. Based at least in part on a viewing angle mode selected by the user, the controller 301 generates a control signal for varying a driving current by a difference value between a preset target value and a current gap value between the first and second substrates 100 and 200, the current gap value being received from the sensor unit 304. After receiving the control signal, the controller 301 generates a driving current based at least in part on the control signal, and supplies the driving current to the piezoelectric actuator 303. Based at least in part on the driving current supplied from the driver 302, the piezoelectric actuator 303 adjusts the gap by contracting or expanding in a direction of the gap between the first and second substrates 100 and 200. Afterward, by measuring an actual length of the piezoelectric actuator 303, the sensor unit 304 re-detects the gap between the first and second substrates 100 and 200. In this case, since the gap between the first and second substrates 100 and 200 is adjusted, the cell gap d is automatically adjusted.

In order to realize the aforementioned mechanism, a space in the cell gap d, for example, the space between the OLED covered with the encapsulation member 210 and the color filter 211, can be in a vacuum state, or can be filled with a material capable of contracting or expanding.

As described above, during the wide viewing angle mode, the piezoelectric actuator 303 contracts and thus the cell gap d is decreased. Conversely, during the narrow viewing angle mode, the piezoelectric actuator 303 expands and thus the cell gap d is increased.

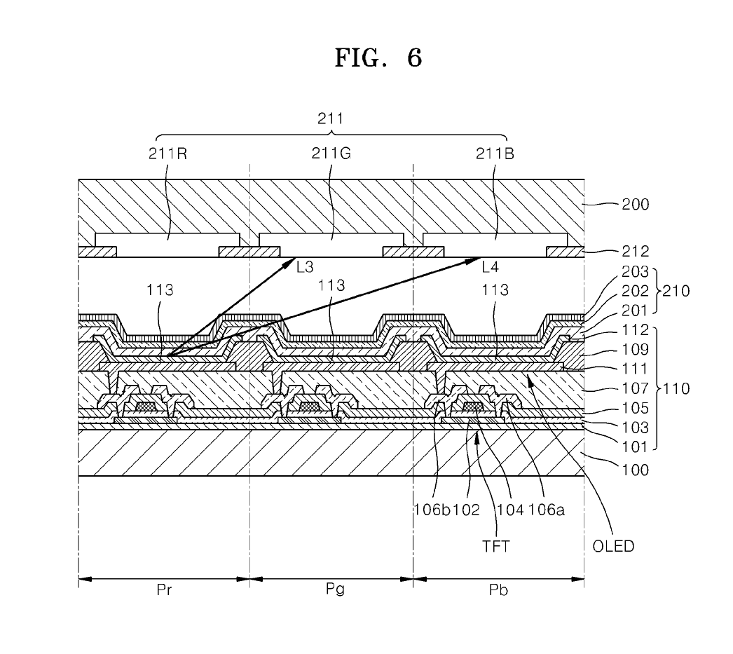

FIG. 6 is a cross-sectional view that illustrates a portion of the display device of FIG. 1 when a color mixture occurs.

As illustrated in FIG. 6, when a distance between the OLED and the color filter 211 is large, for example, when the display device operates in a narrow viewing angle mode, a portion of light emitted from the organic emission layer 113 enters neighboring emission areas. However, according to some embodiments, the occurrence of a color mixture can be solved by using the color filter 211. For example, even if red lights L3 and L4 that are emitted from a red pixel Pr reach a green pixel Pg and a blue pixel Pb, the red lights L3 and L4 are substantially blocked by the green color filter 211G and the blue color filter 211B, so that a possibility of occurrence of a color mixture can be prevented.

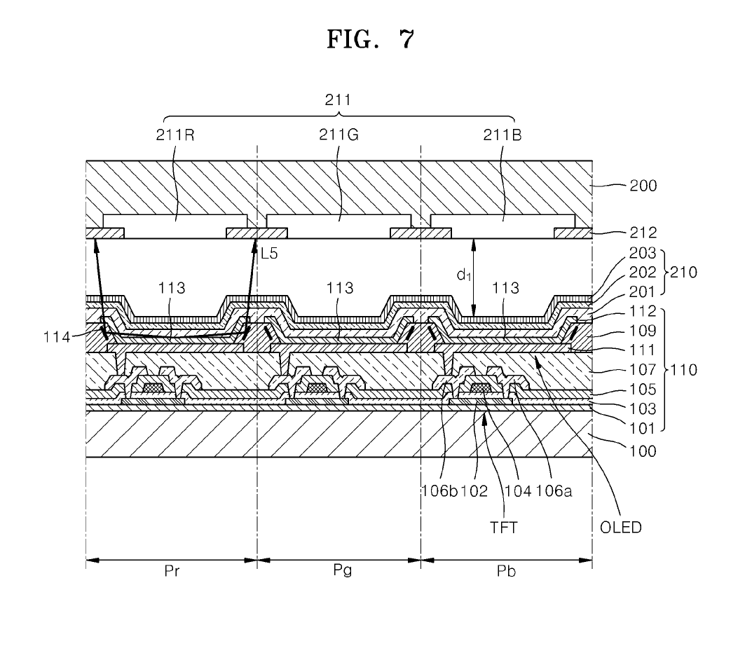

FIG. 7 is a cross-sectional view illustrating a portion of a display device, according to another embodiment.

The display unit 110 can further include the pixel-defining layer 109 that defines a plurality of emission areas, and a reflective member 114 can be formed in the pixel-defining layer 109.

The pixel-defining layer 109 is formed not to cover at least a portion of the pixel electrode 111. The pixel-defining layer 109 can be formed by using various insulating materials, e.g., an organic material or an inorganic material.

In some embodiments, the pixel-defining layer 109 is formed by using at least one organic insulating material selected from the group including polyimide, polyamide, acryl resin, benzocyclobutene, and phenol resin, by using a spin coating method or the like. A predetermined opening that exposes a center portion of the pixel electrode 111 is formed in the pixel-defining layer 109, and the organic emission layer 113 that emits light is deposited in a region defined by the opening to define an emission area.

The reflective member 114 can reduce or substantially block emission of light L5 that is horizontally emitted from the OLED to other emission areas adjacent to the emission area.

For example, the reflective member 114 is formed at a path where light that is generated in the OLED of the pixel is emitted toward another pixel.

To do so, the reflective member 114 is formed in the pixel-defining layer 109.

In some embodiments, the reflective member 114 is formed in a region adjacent to the organic emission layer 113. Since the reflective member 114 is formed in the pixel-defining layer 109, the reflective member 114 can be separated from the organic emission layer 113.

In some embodiments, the reflective member 114 is formed in a region outside the pixel-defining layer 109, and in this case, the reflective member 114 contacts the organic emission layer 113.

In some embodiments, the reflective member 114 is formed while substantially surrounding the organic emission layer 113.

In some embodiments, the reflective member 114 is formed to be separated from the pixel electrode 111, and in some embodiments, the reflective member 114 contacts the pixel electrode 111.

In order to allow the reflective member 114 to efficiently decrease or substantially block the light L5 that is horizontally emitted from the OLED to another emission area adjacent to the emission area, the reflective member 114 can have an predetermined height.

Also, the reflective member 114 can have an angle to make a slope with respect to a top surface of the pixel electrode 111. For example, the reflective member 114 makes an obtuse angle with the top surface of the pixel electrode 111. However, the embodiments are not limited thereto, and the reflective member 114 can make an acute angle with the top surface of the pixel electrode 111.

In some embodiments, one of the surfaces of the reflective member 114 that faces the organic emission layer 113 is formed substantially parallel to a surface of the organic emission layer 113.

The reflective member 114 can be formed of a material such as aluminum (Al), an Al-alloy, silver (Ag), an Ag-alloy, gold, or an Au-alloy, which has excellent reflectance.

By forming the reflective member 114, the possibility of occurrence of a color mixture can be significantly decreased, and a converging performance can be improved, so that a luminescent efficiency can be increased.

It should be understood that the exemplary embodiments described therein should be considered in a descriptive sense only and not for purposes of limitation. Descriptions of features or aspects within each embodiment should typically be considered as available for other similar features or aspects in other embodiments.

While the inventive technology has been described with reference to the figures, it will be understood by those of ordinary skill in the art that various changes in form and details can be made therein without departing from the spirit and scope of the present invention as defined by the following claims.

What is claimed is:

1. A display device comprising:
a first substrate;
a second substrate facing the first substrate;
a display unit comprising a plurality of emission areas formed over a surface of the first substrate facing the second substrate, wherein the emission areas include a plurality of organic light-emitting diodes (OLEDs);
a plurality of black matrices formed over a surface of the second substrate facing the first substrate, wherein the black matrices at least partially overlap side portions of the emission areas; and
a gap controller formed between the first and second substrates and configured to adjust a gap therebetween.

2. The display device of claim 1, further comprising a plurality of color filters formed adjacent to the black matrices and respectively corresponding to the emission areas.

3. The display device of claim 1, wherein the gap controller is further configured to increase or decrease the gap based at least in part on an electrical signal.

4. The display device of claim 3, wherein the gap controller comprises a piezoelectric actuator configured to contract or expand based at least in part on the electrical signal.

5. The display device of claim 4, wherein the piezoelectric actuator is formed in the sides of the display unit between the first and second substrates.

6. The display device of claim 4, wherein the piezoelectric actuator is formed in a region at least partially overlapping the display unit between the first and second substrates.

7. The display device of claim 4, wherein the gap controller further comprises:
a controller configured to i) receive viewing angle mode information and ii) generate a control signal based at least in part on the viewing angle mode information; and
a driver configured to i) receive the control signal from the controller, ii) generate the electrical signal based at least in part on the control signal, and iii) provide the electrical signal to the piezoelectric actuator.

8. The display device of claim 7, wherein the gap controller further comprises a sensor configured to detect a size of the gap between the first and second substrates.

9. The display device of claim 8, wherein the controller is further configured to generate the control signal based at least in part on a difference between a target gap corresponding to the viewing angle mode information and a current gap detected by the sensor.

10. The display device of claim 7, wherein, in a wide viewing angle mode, the piezoelectric actuator is further configured to contract so as to decrease the gap.

11. The display device of claim 7, wherein, in a narrow viewing angle mode, the piezoelectric actuator is further configured to expand so as to increase the gap.

12. The display device of claim 1, further comprising a plurality of reflective members respectively formed outside the emission areas and configured to reflect light output from OLEDs.

13. The display device of claim 12, wherein the display unit further comprises pixel-defining layers that define the emission areas, and wherein the reflective members are respectively formed in the pixel-defining layers.

14. The display device of claim 12, wherein the reflective member is formed on a path where light, substantially horizontally output from a selected one of the OLEDs toward an adjacent OLED.

15. The display device of claim 12, wherein a selected on of the reflective members has an inclined surface facing the one of the OLEDs.

16. The display device of claim 1, further comprising an encapsulation member formed over the first substrate so as to at least partially cover the display unit and comprising at least one insulating layer.

17. The display device of claim 1, wherein a plurality of organic light-emitting diodes (OLEDs) are configured to output light toward the second substrate or toward the first and second substrates.

18. A flexible display comprising:
first and second flexible substrates facing each other;
a display unit comprising a plurality of pixels formed over a surface of the first flexible substrate facing the second flexible substrate; and
a gap controller formed between the first and second flexible substrates and configured to adjust a gap therebetween.

19. The display device of claim 18, wherein the gap controller is further configured to increase or decrease the gap based at least in part on an electrical signal.

20. The display device of claim 19, wherein the gap controller comprises a piezoelectric actuator configured to contract or expand based at least in part on the electrical signal.
